(19) United States
(12) Patent Application Publication
(10) Pub. No.: US 2024/0404799 A1
(43) Pub. Date: Dec. 5, 2024

(54) PLASMA PROCESSING APPARATUS

(71) Applicant: Tokyo Electron Limited, Tokyo (JP)

(72) Inventors: Shota EZAKI, Miyagi (JP); Shinya ISHIKAWA, Miyagi (JP)

(73) Assignee: Tokyo Electron Limited, Tokyo (JP)

(21) Appl. No.: 18/804,728

(22) Filed: Aug. 14, 2024

Related U.S. Application Data
(63) Continuation of application No. PCT/JP2023/003584, filed on Feb. 3, 2023.
(60) Provisional application No. 63/268,004, filed on Feb. 15, 2022.

(30) Foreign Application Priority Data
Jan. 19, 2023 (JP) 2023-006578

(51) Int. Cl. H01J 37/32

(52) U.S. Cl. CPC H01J 37/32724; H01J 2237/2007

(57) ABSTRACT

An electronic device installed in a plasma processing apparatus is protected during an operation of an interlock mechanism of the plasma processing apparatus. A plasma processing apparatus includes: a plasma processing chamber; a base disposed in the plasma processing chamber and having a heat transfer medium flow path and a space; an electrostatic chuck disposed on the base; a first heater element disposed in the electrostatic chuck; a second heater element disposed in the space; a control circuit substrate disposed in the space and including at least one control element electrically connected to at least one of the first heater element and the second heater element; and a recovery circuit electrically connected between the second heater element and the at least one control element and supplying power to the second heater element based on a temperature in the space.

### CROSS-REFERENCE TO RELATED APPLICATIONS

This application is a bypass continuation application of international application No. PCT/JP2023/003584 having an international filing date of Feb. 3, 2023 and designating the United States, the international application being based upon and claiming the benefits of priorities from U.S. provisional application No. 63/268,004, filed on Feb. 15, 2022 and Japanese Patent Application No. 2023-006578, filed on Jan. 19, 2023, the entire contents of each are incorporated herein by reference.

### TECHNICAL FIELD

The present disclosure relates to a plasma processing apparatus.

### BACKGROUND

Patent Document 1 discloses an interlock mechanism that stops supply of power to a plasma processing space when an abnormality occurs in a plasma processing apparatus.

### CITATION LIST

### Patent Documents

Patent Document 1: JP2022-122425A

### SUMMARY

With a technique according to the present disclosure, an electronic device installed in a plasma processing apparatus is protected during an operation of an interlock mechanism of the plasma processing apparatus.

An aspect of the present disclosure is a plasma processing apparatus. The plasma processing apparatus includes: a plasma processing chamber; a base disposed in the plasma processing chamber and having a heat transfer medium flow path and a space; an electrostatic chuck disposed on the base; a first heater element disposed in the electrostatic chuck; a second heater element disposed in the space; a control circuit substrate disposed in the space and including at least one control element electrically connected to at least one of the first heater element and the second heater element; and a recovery circuit electrically connected between the second heater element and the at least one control element and configured to supply power to the second heater element based on a temperature in the space.

According to the present disclosure, an electronic device installed in a plasma processing apparatus can be protected during an operation of an interlock mechanism of the plasma processing apparatus.

### BRIEF DESCRIPTION OF DRAWINGS

FIG. 1 is a view illustrating an example of a configuration of a plasma processing system.

FIG. 2 is a view illustrating an example of a configuration of a capacitively-coupled plasma processing apparatus.

FIG. 3 is a cross-sectional view illustrating an outline of an example of a configuration of a substrate support.

FIG. 4 is a view illustrating an example of an upper surface of an electrostatic chuck.

FIG. 5 is a top view illustrating an example of a configuration of a first control circuit substrate.

FIG. 6 is a top view illustrating an example of a configuration of a second control circuit substrate.

FIG. 7 is a view illustrating an example of a configuration of a recovery circuit.

FIG. 8A is a view illustrating an operation of the recovery circuit.

FIG. 8B is a view illustrating the operation of the recovery circuit.

FIG. 9A is a view illustrating the operation of the recovery circuit.

FIG. 9B is a view illustrating the operation of the recovery circuit.

FIG. 9C is a view illustrating the operation of the recovery circuit.

FIG. 9D is a view illustrating the operation of the recovery circuit.

FIG. 10 is a view illustrating an effect of the recovery circuit.

FIG. 11 is a view illustrating a configuration of the recovery circuit according to a modification.

FIG. 12 is a view illustrating a configuration of the recovery circuit according to a modification.

FIG. 13 is a view illustrating a configuration of the recovery circuit according to a modification.

FIG. 14 is a view illustrating a configuration of the recovery circuit according to a modification.

### DETAILED DESCRIPTION

A plasma processing apparatus and a substrate support according to the present embodiment will be described with reference to the drawings. Like reference numerals will be given to like parts having substantially the same functions throughout the specification and the drawings, and redundant description thereof will be omitted.

### <Plasma Processing System>

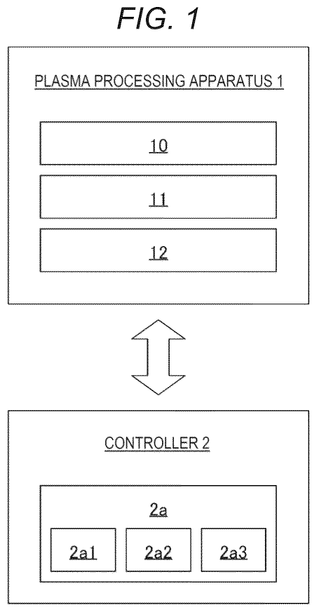

A plasma processing system according to one embodiment will be described with reference to FIG. 1.

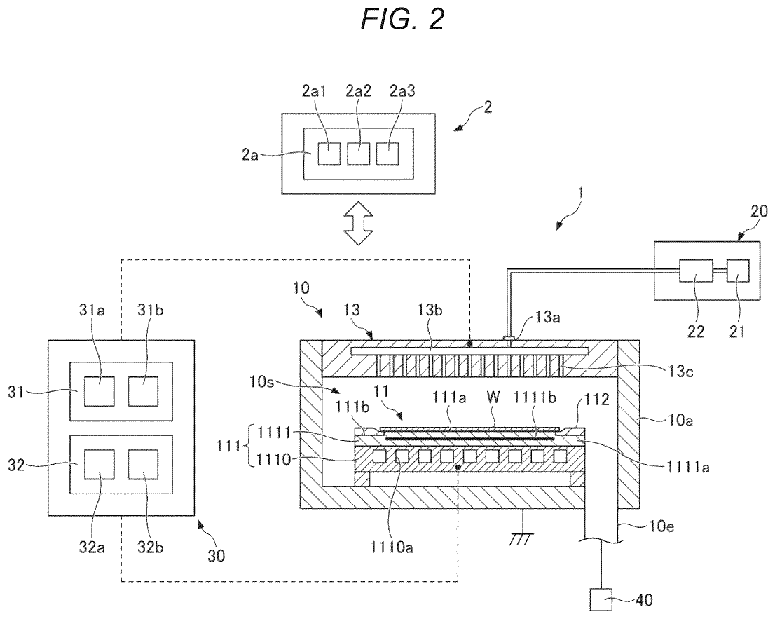

FIG. 1 is a diagram illustrating an example of a configuration of a plasma processing system. In an embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space 10s (see FIG. 2 which will be described later). The plasma processing chamber 10 has at least one gas supply port to supply at least one processing gas into the plasma processing space 10s, and at least one gas exhaust port to exhaust the gas from the plasma processing space 10s. The gas supply port is connected to a gas supply 20 which will be described later, and the gas exhaust port is connected to an exhaust system 40 which will be described later. The substrate support 11 is disposed in the plasma processing space 10s and has a substrate support surface to support a substrate W (see FIG. 2 which will be described later).

The plasma generator 12 is configured to generate plasma from at least one processing gas supplied into the plasma processing space 10s. The plasma formed in the plasma processing space may be Capacitively Coupled Plasma (CCP), Inductively Coupled Plasma (ICP), Electron-Cyclotron-Resonance Plasma (ECR plasma), Helicon Wave Plasma (HWP), Surface Wave Plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions instructing the plasma processing apparatus 1 to execute various steps described herein below. The controller 2 may be configured to control the respective components of the plasma processing apparatus 1 to execute the various steps described herein below. In an embodiment, part or all of the controller 2 may be provided in the plasma processing apparatus 1. The controller 2 may include a processor 2al, a storage unit 2a2, and a communication interface 2a3. The controller 2 is implemented by, for example, a computer 2a. The processor 2al may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2al. The medium may be various storing media readable by the computer 2a, or may be a communication line connected to the communication interface 2a3. The processor 2al may be a Central Processing Unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

Hereinafter, a configuration example of a capacitively-coupled plasma processing apparatus as an example of the plasma processing apparatus 1 will be described. FIG. 2 is a view illustrating an example of a configuration of a capacitively-coupled plasma processing apparatus.

The capacitively-coupled plasma processing apparatus 1 includes the plasma processing chamber 10, the gas supply 20, a power source 30, and the exhaust system 40. Further, the plasma processing apparatus 1 includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has the plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a dielectric member 1111a and an attraction electrode layer (also referred to as an electrostatic electrode layer, a chuck electrode layer, and a clamp electrode layer) 1111b disposed in the dielectric member 1111a. The dielectric member 1111a has the central region 111a. In one embodiment, the dielectric member 1111a also has the annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. At least one RF/DC electrode coupled to an RF power source 31 and/or a DC power source 32 which will be described later may be disposed in the dielectric member 1111a. In this case, at least one RF/DC electrode functions as the lower electrode. In a case where the bias RF signal and/or the DC signal to be described later are supplied to at least one RF/DC electrode, the RF/DC electrode is also referred to as a bias electrode. The conductive member of the base 1110 and at least one RF/DC electrode may function as a plurality of lower electrodes. The attraction electrode layer 1111b may function as a lower electrode. Accordingly, the substrate support 11 includes at least one lower electrode.

In one embodiment, the base 1110 has a space which will be described later. A first control circuit substrate and a second control circuit substrate which will be described later are disposed in the space. The first control circuit substrate and the second control circuit substrate are supplied with power from the power source 30 which will be described later. The space is controlled to a constant temperature by the second control circuit substrate in order to prevent the temperature from falling to a low temperature by a heat transfer medium which will be described later. The constant temperature is, for example, 100° C.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a heat transfer medium flow path 1110a, or a combination thereof. A heat transfer fluid, such as brine or gas, flows through the heat transfer medium flow path 1110a. In one embodiment, the heat transfer medium flow path 1110a is formed in the base 1110, and one or a plurality of heaters are disposed in the dielectric member 1111a of the electrostatic chuck 1111. Further, the substrate support 11 may include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied into the plasma processing space 10s. Accordingly, the RF power source 31 may function as at least a part of the plasma generator 12. Further, supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include the DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first DC signal is applied to at least one lower electrode. In one embodiment, the second DC generator 32b is configured to be connected to at least one upper electrode to generate a second DC signal. The generated second DC signal is applied to at least one upper electrode.

In various embodiments, the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one embodiment, a waveform generator to generate a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The plasma processing apparatus 1 includes an interlock mechanism (not illustrated). The interlock mechanism is a system that stops supply of power to the plasma processing chamber 10 when any abnormal state occurs in the plasma processing apparatus 1. The abnormal state refers to, for example, a temperature abnormality or a communication failure due to a disconnection of an interconnect. When the interlock mechanism operates, the supply of power from the power source 30 to the second control circuit substrate described above is also stopped. Accordingly, the space in the base 1110 described above is rapidly brought into a low-temperature state by the heat transfer medium flowing through the heat transfer medium flow path.

### <Substrate Support>

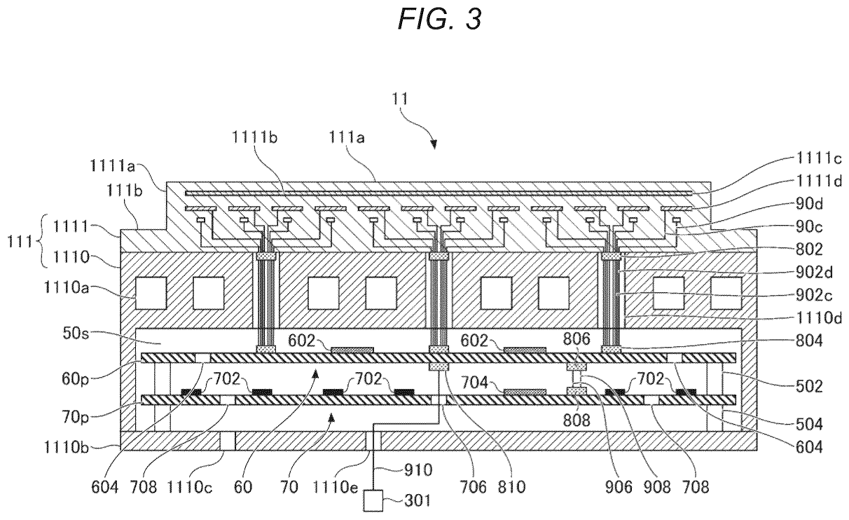

A configuration of the substrate support 11 will be described with reference to FIG. 3. FIG. 3 is a cross-sectional view illustrating an outline of an example of the configuration of the substrate support 11 according to one embodiment. As described above, the main body 111 of the substrate support 11 includes the electrostatic chuck 1111 and the base 1110.

The electrostatic chuck 1111 includes the dielectric member 1111a as described above. The dielectric member 1111a is formed into a substantially circular plate shape. The dielectric member 1111a is formed of a ceramic material such as aluminum oxide or aluminum nitride. The dielectric member 1111a has the central region 111a and the annular region 111b described above. The dielectric member 1111a may be formed by thermal spraying of a ceramic material.

In one embodiment, the central region 111a has a diameter smaller than a diameter of the substrate W and is located higher than the annular region 111b. Accordingly, when the substrate W is supported on the central region 111a, a peripheral portion of the substrate W horizontally protrudes from the central region 111a.

In an example in FIG. 3, an upper surface of the dielectric member 1111a integrally formed has the central region 111a and the annular region 111b. The dielectric member 1111a may be divided into a central portion and an annular portion. In this case, an upper surface of the central portion has the central region 111a, and an upper surface of the annular portion ha s the annular region 111b. In the example in FIG. 3, the central portion and the annular portion are integrally formed. However, the central portion and the annular portion may be separately formed.

The dielectric member 1111a includes the attraction electrode layer 1111b disposed below the central region 111a. Power from an AC power source or a DC power source (not illustrated) is applied to the attraction electrode layer 1111b. The substrate W is attracted and held onto the central region 111a by an electrostatic force thus generated. That is, the attraction electrode layer 1111b functions as an attraction electrode layer of the substrate W. In one embodiment, the attraction electrode layer 1111b is formed in a circular shape in a plan view. For example, the attraction electrode layer 1111b may have a plurality of electrode layer segments divided in a radial direction and/or a circumferential direction. The dielectric member 1111a may include an attraction electrode layer disposed below the annular region 111b. In this case, the attraction electrode layer disposed below the annular region 111b functions as an attraction electrode layer of the ring assembly (edge ring) 112.

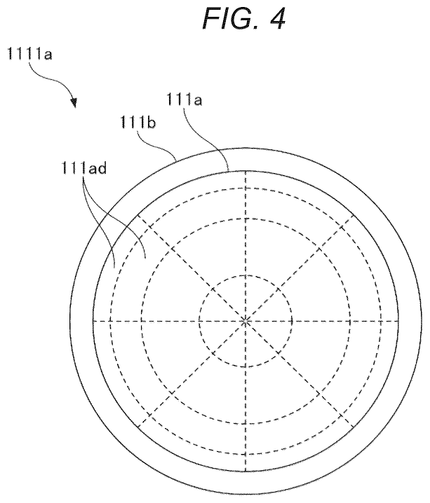

FIG. 4 is a view illustrating an example of an upper surface of the electrostatic chuck 1111. The central region 111a of the dielectric member 1111a of the electrostatic chuck 1111 is divided into a plurality of divided regions (also referred to as zones) 111ad, for example, as shown in FIG. 4. In FIG. 4, each of the divided regions 111ad is separated by a broken line. As shown in FIG. 3, a heater electrode layer 111c (first heater element) is disposed below the attraction electrode layer 1111b in each of the divided regions 111ad. The heater electrode layer 111c is, for example, a resistance heating type heater. The heater electrode layers 1111c individually control the temperature in each divided region 111ad of the central region 111a. Accordingly, temperature uniformity of the substrate W can be improved. In the examples in FIGS. 3 and 4, one heater electrode layer 1111c is disposed in each of the divided regions 111ad. However, the present disclosure is not limited thereto. One heater electrode layer 1111c may be disposed for each of the plurality of divided regions 111ad. A plurality of heater electrode layers 1111c may be disposed in one divided region 111ad. In the examples in FIGS. 3 and 4, the annular region 111b is not divided into a plurality of divided regions. However, the annular region 111b may be divided into a plurality of divided regions. In this case, the heater electrode layer 1111c may be disposed below the attraction electrode layer of the ring assembly (edge ring) 112 for each of the plurality of divided regions of the annular region 111b. That is, at least one heater electrode layer 111c is disposed in the electrostatic chuck 1111. In one embodiment, the at least one heater electrode layer 111c includes a plurality of heater electrode layers 111c.

A plurality of temperature sensors 1111d are disposed below each of the plurality of heater electrode layers 111c in the dielectric member 1111a. The plurality of temperature sensors 111d detect, as an electric signal, a temperature in the heater electrode layer 1111c disposed above each of the plurality of temperature sensors 1111d. The plurality of heater electrode layers 1111c are controlled, based on output from the plurality of temperature sensors 1111d, by a first control circuit substrate 60 which will be described later. In the example in FIG. 3, the temperature sensor 1111d is disposed below each of the heater electrode layers 1111c. However, the present disclosure is not limited thereto. As long as the temperature sensor 1111d is located near each heater electrode layer 1111c, the temperature sensor 1111d may be disposed above or to the side of the heater electrode layer 1111c. One temperature sensor 1111d may be disposed for each of the plurality of heater electrode layers 111c.

A connector 802 is disposed on a lower surface of the dielectric member 1111a. The plurality of heater electrode layers 111c disposed in the dielectric member 1111a are electrically connected to the first control circuit substrate 60, which will be described later, through an interconnect 90c in the dielectric member 1111a and the connector 802. The plurality of temperature sensors 1111d disposed in the dielectric member 1111a are electrically connected to the first control circuit substrate 60, which will be described later, through an interconnect 90d in the dielectric member 1111a and the connector 802.

The base 1110 is formed of, for example, a conductive material such as aluminum. The base 1110 has the heat transfer medium flow path 1110a described above. In one embodiment, the base 1110 and the electrostatic chuck 1111 are coupled to each other through, for example, an adhesive layer. The base 1110 has therein a space 50s (i.e., interior space) different from the heat transfer medium flow path 1110a. The base 1110 includes a bottom plate 1110b that defines a part of the space 50s. The bottom plate 1110b is detachably attached to the base 1110. By separating the bottom plate 1110b from the base 1110, the first control circuit substrate 60 and a second control circuit substrate 70 which will be described later can be inserted into the space 50s. The bottom plate 1110b of the base 1110 has a supply hole 1110c to supply a low-humidity gas into the space 50s. By supplying the low-humidity gas into the space 50s from the supply hole 1110c, an occurrence of dew condensation at a low temperature in the space 50s can be prevented, and a malfunction or the like caused by moisture in the electronic device disposed in the space 50s can be prevented. In the present embodiment, the low-humidity gas is, for example, dry air. In the example in FIG. 3, the base 1110 is formed of a conductive material. However, the present disclosure is not limited thereto. The base 1110 may be formed of a non-conductive material such as silicon carbide (SiC), aluminum nitride (AlN), and alumina or aluminum oxide (Al₂O₃). The bottom plate 1110b may be formed of a non-conductive material.

The first control circuit substrate 60 that controls the heater electrode layer 111c disposed in the dielectric member 1111a described above based on the output from the temperature sensor 1111d is disposed in the space 50s of the base 1110. The first control circuit substrate 60 includes a printed circuit substrate 60p. A plurality of element control devices (control elements) 602 and a connector 804 are mounted on an upper surface of the printed circuit substrate 60p. A connector 806 and a connector 810 are mounted on a lower surface of the printed circuit substrate 60p. The element control device 602 controls a temperature of the heater electrode layer 111c. The element control device 602 processes the electric signal from the temperature sensor 1111d to perform control to specify the temperature of the heater electrode layer 1111c. As the element control device 602, for example, an electronic circuit such as a central processing unit (CPU) or a micro processing unit (MPU), or an integrated circuit such as an application specific integrated circuit (ASIC) or a field programmable gate array (FPGA) can be employed. The printed circuit substrate 60p has a ventilation through-hole 604. In the example in FIG. 3, two element control devices 602 are mounted on the printed circuit substrate. However, the present disclosure is not limited thereto. The number of element control devices 602 may be one, or may be three or more, depending on the number of heater electrode layers 111c and temperature sensors 111d to be controlled. That is, the first control circuit substrate 60 includes at least one element control device 602. Temperature control of the heater electrode layer 111c and processing of the electric signal from the temperature sensor 111d may be performed by one element control device 602, or the temperature control of the heater electrode layer 111c and the processing of the electric signal from the temperature sensor 1111d may be performed by different element control devices 602, respectively. The ventilation through-hole 604 in the printed circuit substrate 60P may not be formed.

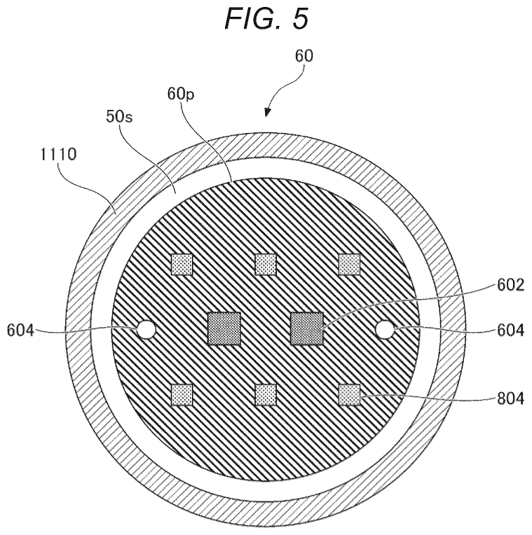

FIG. 5 is a top view illustrating an example of a configuration of the first control circuit substrate 60. In one embodiment, the space 50s in the base 1110 has a substantially cylindrical shape. The printed circuit substrate 60p has a diameter smaller than a diameter of the space 50s, and a gap between the base 1110 and the printed circuit substrate 60p is formed. In the present embodiment, the space 50s and the printed circuit substrate 60p have a circular shape in a top view. However, the present disclosure is not limited thereto. The space 50s and the printed circuit substrate 60p may have an oval shape or a polygonal shape. Disposition positions of the element control device 602, the connector 804, and the ventilation through-hole 604 are not limited to the configuration in FIG. 5.

The base 1110 has a plurality of through-holes 1110d, and a cable interconnect 902c and a cable interconnect 902d extend in the through-hole 1110d in a vertical direction. The heater electrode layer 1111c is electrically connected to the element control device 602 through the interconnect 90c in the dielectric member 1111a, the connector 802 disposed on the lower surface of the dielectric member 1111a, the cable interconnect 902c, the connector 804, and an interconnect on a surface layer or an inner layer of the printed circuit substrate 60p. The temperature sensor 1111d is electrically connected to the element control device 602 through the interconnect 90d in the dielectric member 1111a, the connector 802 disposed on the lower surface of the dielectric member 1111a, the cable interconnect 902d, the connector 804, and the interconnect on the surface layer or the inner layer of the printed circuit substrate 60p.

The connector 810 mounted on the lower surface of the printed circuit substrate 60p is disposed to supply power to the first control circuit substrate 60. The element control device 602 of the first control circuit substrate 60 is connected to a power source 301 through the interconnect on the surface layer or the inner layer of the printed circuit substrate 60p, the connector 810, and an interconnect 910 passing through a through-hole 706 formed in a printed circuit substrate 70p and a through-hole 1110e formed in the bottom plate 1110b of the base 1110. The power source 301 may be provided in the power source 30 described above, or may be an external power source other than the power source 30. The element control device 602 of the first control circuit substrate 60 may receive power from an external power source other than the power source 30.

The second control circuit substrate 70 that controls the temperature in the space 50s of the base 1110 is further disposed in the space 50s of the base 1110. The second control circuit substrate 70 includes the printed circuit substrate 70p. A recovery circuit 704 which will be described later, a heater element 702 (second heater element), and a connector 808 are mounted on an upper surface of the printed circuit substrate 70p. The heater element 702 is, for example, a resistance heating type heater. The heater element 702 is electrically connected to the element control device 602 through an interconnect on a surface layer or an inner layer of the printed circuit substrate 70p, the connector 808, an interconnect 906, an interconnect 908, the connector 806, and the interconnect on the surface layer or the inner layer of the printed circuit substrate 60p. The interconnect 906 is a power feeding interconnect of the recovery circuit which will be described later. The interconnect 908 is a reference potential interconnect of a recovery circuit which will be described later. The element control device 602 controls not only the temperature control of the heater electrode layer 1111c and the processing of the electric signal from the temperature sensor 1111d described above, but also controls the temperature in the space 50s by controlling the heater element 702. The temperature in the space 50s is measured by a temperature sensor (not illustrated) disposed in the space 50s, and the element control device 602 controls the heater element 702 based on the temperature in the space 50s measured by the temperature sensor. In the example in FIG. 3, a ventilation through-hole 708 is formed in the printed circuit substrate 70p. However, the through-hole 708 may be omitted.

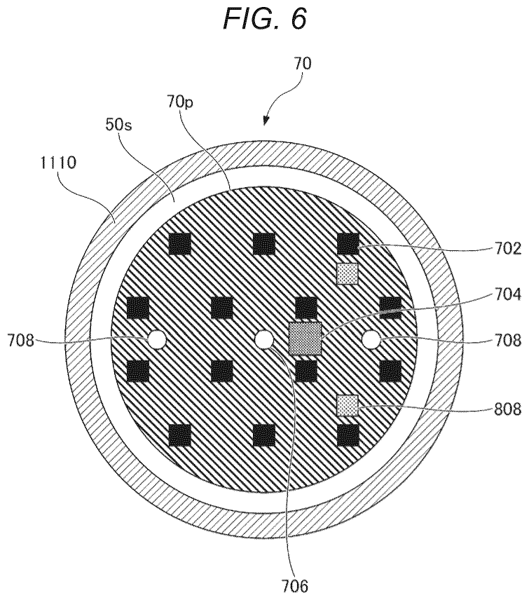

FIG. 6 is a top view illustrating an example of a configuration of the second control circuit substrate. In one embodiment, the printed circuit substrate 70p has a diameter smaller than the diameter of the space 50s, and a gap between the base 1110 and the printed circuit substrate 70p is formed. The printed circuit substrate 70p has a diameter substantially the same as that of the printed circuit substrate 60p. In the present embodiment, the printed circuit substrate 70p has a circular shape in a top view. However, the present disclosure is not limited thereto. The printed circuit substrate 70p may have an oval shape or a polygonal shape. The printed circuit substrate 70p may have a size or shape different from that of the printed circuit substrate 60p. Disposition positions of the recovery circuit 704, the heater element 702, the connector 808, and the ventilation through-hole 708 are not limited to the configuration in FIG. 6.

The printed circuit substrate 60p and the printed circuit substrate 70p are fixed to the bottom plate 1110b through a spacer 502 and a spacer 504 in the space 50s. The printed circuit substrate 60p and the printed circuit substrate 70p are spaced apart from each other in the space 50s.

In the example in FIG. 3, the recovery circuit 704 is mounted on the printed circuit substrate 70p of the second control circuit substrate 70. However, the present disclosure is not limited thereto. The recovery circuit 704 may be mounted on the printed circuit substrate 60p of the first control circuit substrate 60. The recovery circuit 704 may also be mounted on another printed circuit substrate provided separately within the space 50s.

In the example in FIG. 3, the second control circuit substrate 70 is disposed below the first control circuit substrate 60 in the space 50s of the base 1110. However, the present disclosure is not limited thereto. The second control circuit substrate 70 may be disposed above the first control circuit substrate 60. A plurality of second control circuit substrates 70 may be disposed in the space 50s of the base 1110. In this case, the recovery circuits 704 may be provided in the respective second control circuit substrates 70.

### <Recovery Circuit>

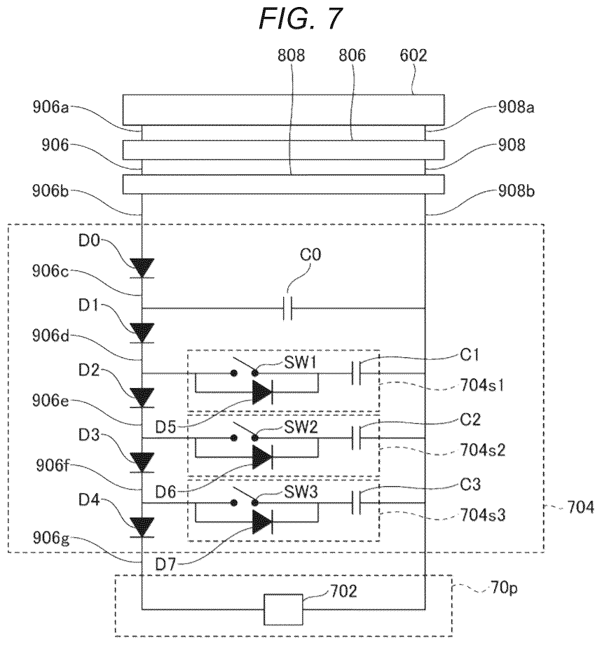

A configuration of the recovery circuit 704 will be described with reference to FIG. 7.

FIG. 7 is a view illustrating an example of the configuration of the recovery circuit 704 according to one embodiment.

The recovery circuit 704 is disposed between the element control device 602 mounted on the printed circuit substrate 60p and the heater element 702 mounted on the printed circuit substrate 70p. The recovery circuit 704 is electrically connected to a power feeding interconnect 906b and a reference potential interconnect 908b formed in the surface layer or the inner layer of the printed circuit substrate 70p. The power feeding interconnect 906b is provided to supply power from the element control device 602 of the first control circuit substrate 60 to a first circuit segment 704s1, a second circuit segment 704s2, and a third circuit segment 704s3 of the recovery circuit 704. The reference potential interconnect 908b is provided to determine a reference potential for each element of the recovery circuit 704. The reference potential is, for example, a ground potential. The power feeding interconnect 906b is electrically connected to the power feeding interconnect 906 described above through the connector 808. The power feeding interconnect 906 is electrically connected to the element control device 602 through the connector 806 and a power feeding interconnect 906a formed on the surface layer or the inner layer of the printed circuit substrate 60p. Similarly, the reference potential interconnect 908b is electrically connected to the reference potential interconnect 908 described above through the connector 808. The reference potential interconnect 908 is electrically connected to the element control device 602 through the connector 806 and a reference potential interconnect 908a formed on the surface layer or the inner layer of the printed circuit substrate 60p. In the example in FIG. 7, power is supplied from the element control device 602 to the first circuit segment 704s1, the second circuit segment 704s2, and the third circuit segment 704s3 of the recovery circuit 704. However, the present disclosure is not limited thereto. Other control devices (second control elements) may be mounted on the printed circuit substrate 60p or the printed circuit substrate 70p, and power may be supplied from the other control devices to the first circuit segment 704s1, the second circuit segment 704s2, and the third circuit segment 704s3 of the recovery circuit 704.

The recovery circuit 704 is electrically connected to the heater element 702 through a power feeding interconnect 906g and the reference potential interconnect 908b.

The recovery circuit 704 includes a plurality of circuit segments electrically connected between the at least one element control device 602 and at least one heater element 702 and connected in parallel. The plurality of circuit segments include the first circuit segment 704s1, the second circuit segment 704s2, and the third circuit segment 704s3. Accordingly, the first circuit segment 704s1, the second circuit segment 704s2, and the third circuit segment 704s3 are electrically connected in parallel. The first circuit segment 704s1 includes a first switch element SW1, a first capacitor C1, and a first diode D5. The first capacitor C1 is an example of a first power storage element. The first diode D5 is an example of a first parallel rectifying element. The first capacitor C1 is connected in series with the first switch element SW1. The first diode D5 is connected in parallel with the first switch element SW1. The second circuit segment 704s2 includes a second switch element SW2, a second capacitor C2, and a second diode D6. The second capacitor C2 is an example of a second power storage element. The second diode D6 is an example of a parallel rectifying element. The second capacitor C2 is connected in series with the second switch element SW2. The second diode D6 is connected in parallel with the second switch element SW2. The third circuit segment 704s3 includes a third switch element SW3, a third capacitor C3, and a third diode D7. The third capacitor C3 is an example of a third power storage element. The third diode D7 is an example of a third parallel rectifying element. The third capacitor C3 is connected in series with the third switch element SW3. The third diode D7 is connected in parallel with the third switch element SW3. In the example in FIG. 7, the three circuit segments 704s1, 704s2, and 704s3 are connected in parallel. However, the present disclosure is not limited thereto. For example, at least one circuit segment may be provided. In one embodiment, four or more circuit segments connected in parallel may be provided. The first to third power storage elements are a capacitor. However, the present disclosure is not limited thereto. The first to third power storage elements may be a substrate-mounted battery. The first to third parallel rectifying elements are a diode. However, the present disclosure is not limited thereto. The first to third parallel rectifying elements may be a thyristor. The first diode D5, the second diode D6, and the third diode D7 are provided. However, at least one of the diodes may not be provided.

The first switch element SW1, the second switch element SW2, and the third switch element SW3 are configured to perform a switching operation based on the temperature in the space 50s, and are, for example, a bimetal thermostat or a reed switch. The first switch element SW1, the second switch element SW2, and the third switch element SW3 are configured to be turned off (opened; non-conductive) at different temperatures, respectively. In the example in FIG. 7, the first switch element SW1 is configured to be turned off (opened; non-conductive) when the temperature in the space 50s exceeds a first temperature, the second switch element SW2 is configured to be turned off (opened; non-conductive) when the temperature in the space 50s exceeds a second temperature, and the third switch element SW3 is configured to be turned off (opened; non-conductive) when the temperature in the space 50s exceeds a third temperature. That is, the first switch element SW1 is configured to be turned on (closed; conductive) when the temperature in the space 50s is lower than or equal to the first temperature, the second switch element SW2 is configured to be turned on (closed; conductive) when the temperature in the space 50s is lower than or equal to the second temperature, and the third switch element SW3 is configured to be turned on (closed; conductive) when the temperature in the space 50s is lower than or equal to the third temperature. In one embodiment, the first temperature is higher than the second temperature and the second temperature is higher than the third temperature. In one embodiment, the first temperature is 95° C. to 85° C., the second temperature is 85° C. to 75° C., and the third temperature is 75° C. to 65° C. In another embodiment, the first temperature is lower than the second temperature, and the second temperature is lower than the third temperature. In another embodiment, the first temperature is 75° C. to 65° C., the second temperature is 85° C. to 75° C., and the third temperature is 95° C. to 85° C. When the bimetal thermostat is used, the first temperature, the second temperature, and the third temperature are set by adjusting a material or shape of bimetal. When the reed switch is used, the first temperature, the second temperature, and the third temperature are set by adjusting a mixing ratio of a soft magnetic material in a switch and adjusting a Curie temperature.

In the example in FIG. 7, a capacitor C0 is electrically connected between the power feeding interconnect 906b and the reference potential interconnect 908b in parallel with the first circuit segment 704s1, the second circuit segment 704s2, and the third circuit segment 704s3. The capacitor C0 is an example of an additional power storage element. As the additional power storage element, a substrate-mounted battery may be used instead of the capacitor C0.

The recovery circuit 704 includes a diode D0 connected between the power feeding interconnect 906b and a power feeding interconnect 906c. Accordingly, the diode D0 is connected between the element control device 602 and an input terminal of the capacitor C0. The diode D0 is a rectifying element for preventing backflow of a current, and is an example of a first series rectifying element. Similarly, the recovery circuit 704 includes a diode D1, a diode D2, a diode D3, and a diode D4. The diode D1 is connected between the power feeding interconnect 906c and a power feeding interconnect 906d. Accordingly, the diode D1 is connected between the input terminal of the capacitor C0 and an input terminal of the first circuit segment 704s1. The diode D1 is an example of a second series rectifying element. The diode D2 is connected between the power feeding interconnect 906d and a power feeding interconnect 906e. Accordingly, the diode D2 is connected between the input terminal of the first circuit segment 704s1 and an input terminal of the second circuit segment 704s2. The diode D2 is an example of a third series rectifying element. The diode D3 is connected between the power feeding interconnect 906e and a power feeding interconnect 906f. Accordingly, the diode D3 is connected between the input terminal of the second circuit segment 704s2 and an input terminal of the third circuit segment 704s3. The diode D3 is an example of a fourth series rectifying element. The diode D4 is connected between the power feeding interconnect 906f and the power feeding interconnect 906g. Accordingly, the diode D4 is connected between the input terminal of the third circuit segment 704s3 and an input terminal of the heater element 702. The diode D4 is an example of a fifth series rectifying element. In the example in FIG. 7, the first to fifth series rectifying elements are a diode. However, the present disclosure is not limited thereto. The first to fifth series rectifying elements may be a thyristor. In the example in FIG. 7, five diodes D0, D1, D2, D3, and D4 are provided. However, at least one of these diodes may not be provided.

### <Operation of Recovery Circuit>

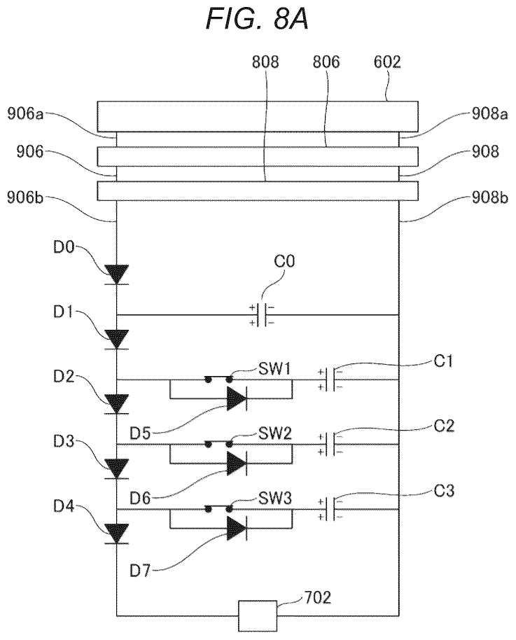

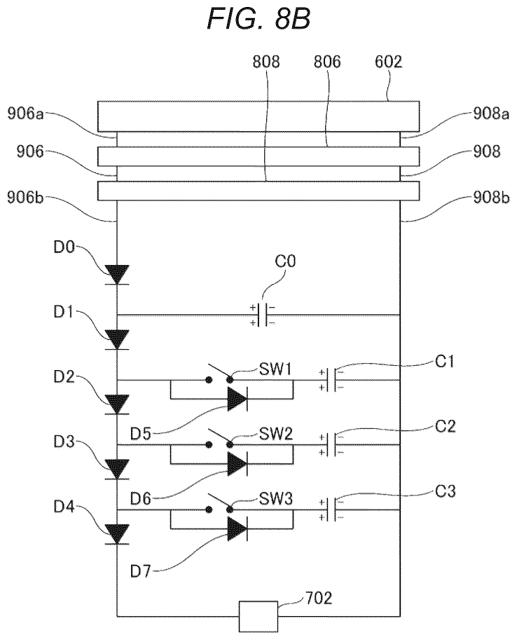

First, an operation of the recovery circuit 704 during a normal operation of the plasma processing apparatus 1 will be described with reference to FIGS. 8A and 8B.

The temperature in the space 50s of the base 1110 in an initial stage when power is applied to the plasma processing apparatus 1 is room temperature. The room temperature is, for example, 20° C. to 30° C. In the initial state, as illustrated in FIG. 8A, all of the first switch element SW1, the second switch element SW2, and the third switch element SW3 are turned on. Accordingly, the capacitor C0 is fully charged by a current flowing from the element control device 602 through the power feeding interconnect 906b and the diode D0. The first capacitor C1 is fully charged by a current flowing from the element control device 602 through the power feeding interconnect 906b, the diode D0, the diode D1, and the first switch element SW1. The second capacitor C2 is fully charged by a current flowing from the element control device 602 through the power feeding interconnect 906b, the diode D0, the diode D1, the diode D2, and the second switch element SW2. The third capacitor C3 is fully charged by a current flowing from the element control device 602 through the power feeding interconnect 906b, the diode D0, the diode D1, the diode D2, the diode D3, and the third switch element SW3. When an electrostatic capacitance of the first capacitor C1 is large, it takes a longer time to full charge. Therefore, the first switch element SW1 may be turned off before the first capacitor C1 is fully charged. In this case, the first capacitor C1 is fully charged by a current flowing from the element control device 602 through the first diode D5 biased in a forward direction. Similarly, when an electrostatic capacitance of the second capacitor C2 is large, the second capacitor C2 is fully charged by a current flowing from the element control device 602 through the second diode D6 biased in the forward direction. When an electrostatic capacitance of the third capacitor C3 is large, the third capacitor C3 is fully charged by a current flowing from the element control device 602 through the third diode D7 biased in the forward direction.

FIG. 8B is a view illustrating a steady state of the recovery circuit 704 according to one embodiment. In the steady state, all of the first switch element SW1, the second switch element SW2, and the third switch element SW3 are turned off. A transition from the initial state illustrated in FIG. 8A to the steady state illustrated in FIG. 8B is as follows. After the initial state where the power is applied to the plasma processing apparatus 1, the temperature in the space 50s gradually increases due to the heater element 702 of the second control circuit substrate 70 disposed in the space 50s. When the temperature in the space 50s reaches the third temperature (for example, 70° C.), the third switch element SW3 is turned off. Thereafter, when the temperature in the space 50s reaches the second temperature (for example, 80° C.), the second switch element SW2 is turned off, and further, when the temperature in the space 50s reaches the first temperature (for example, 90° C.), the third switch element SW3 is turned off, and thus the steady state illustrated in FIG. 8B is obtained.

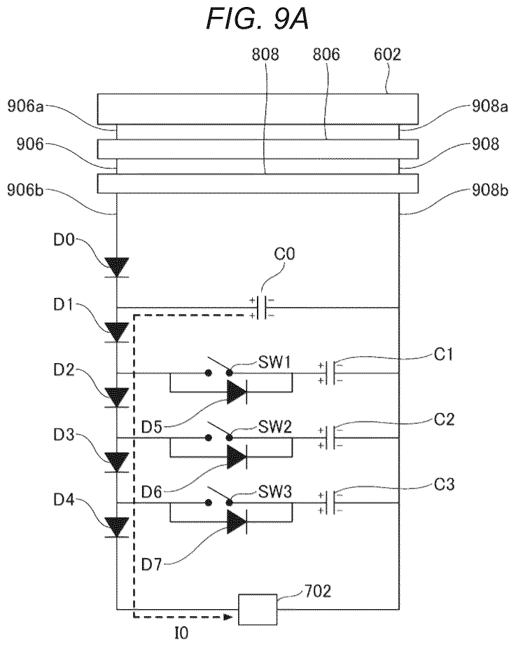

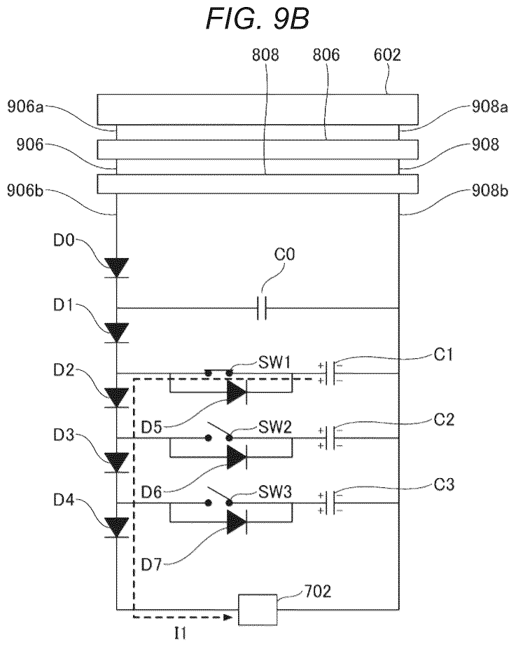

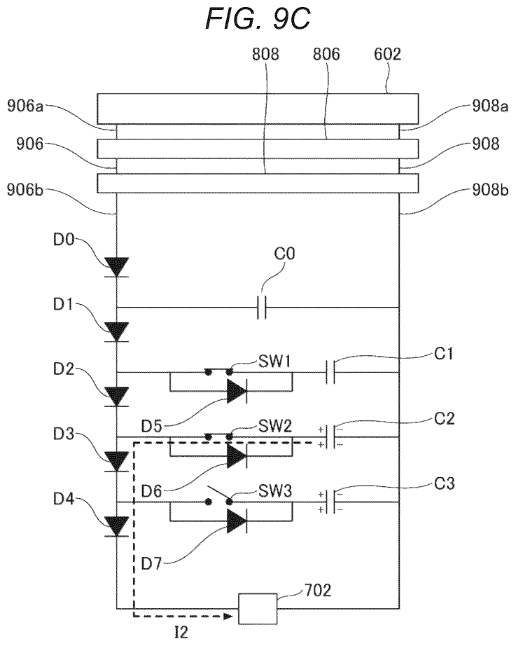

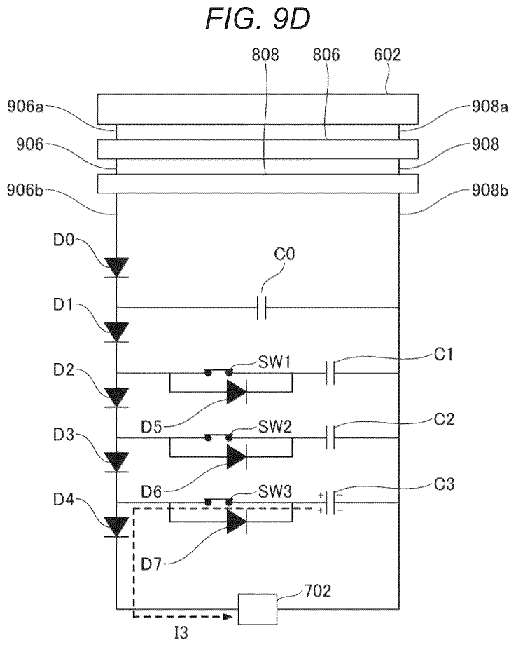

Next, an operation of the recovery circuit 704 when the interlock mechanism of the plasma processing apparatus 1 operates will be described with reference to FIGS. 9A to 9D.

FIG. 9A is a view illustrating the operation of the recovery circuit 704 immediately after the interlock mechanism operates. In the present example, the explanation will be given assuming that the temperature in the space 50s in the steady state illustrated in FIG. 8B before the interlock mechanism operates is 100° C. When the interlock mechanism operates, the supply of power to the first control circuit substrate 60 is stopped, so that the supply of power from the element control device 602 to the heater element 702 is also stopped. When the supply of power from the element control device 602 to the heater element 702 is stopped, first, stored charges are supplied as a current I0 from the fully charged capacitor C0 to the heater element 702 through the diode D1, the diode D2, the diode D3, and the diode D4. Accordingly, even when the interlock mechanism operates and the control of the element control device 602 is stopped, the supply of power to the heater element 702 can be continued. Accordingly, the space 50s in the base 1110 can be prevented or delayed from being rapidly brought into a low-temperature state, and a state within a recommended operating environment temperature of the electronic device disposed in the space 50s can be maintained.

In a case where the current I0 is supplied from the capacitor C0 to the heater element 702 after the interlock mechanism operates, when the temperature in the space 50s decreases to the first temperature (for example, 90° C.), the first switch element SW1 is turned on as illustrated in FIG. 9B. When the first switch element SW1 is turned on, stored charges are supplied as a current I1 from the fully charged first capacitor C1 to the heater element 702 through the diode D2, the diode D3, and the diode D4. Accordingly, not only the capacitor C0 but also the first capacitor C1 can continue to supply the power to the heater element 702. Accordingly, the space 50s in the base 1110 can be prevented or delayed from being rapidly brought into a low-temperature state, and a state within a recommended operating environment temperature of the electronic device disposed in the space 50s can be maintained. In the example in FIG. 9B, only the current I1 from the first capacitor C1 is supplied to the heater element 702. However, the current I1 from the first capacitor C1 and the current I0 from the capacitor C0 may be simultaneously supplied to the heater element 702, according to the electrostatic capacitances of the capacitor C0 and the first capacitor C1.

Further, when the temperature in the space 50s decreases to the second temperature (for example, 80° C.), the second switch element SW2 is turned on as illustrated in FIG. 9C. When the second switch element SW2 is turned on, stored charges are supplied as a current 12 from the fully charged second capacitor C2 to the heater element 702 through the diode D3 and the diode D4. Accordingly, not only the capacitor C0 and the first capacitor C1, but also the second capacitor C2 can continue to supply the power to the heater element 702. Accordingly, the space 50s in the base 1110 can be prevented or delayed from being rapidly brought into a low-temperature state, and the state within a recommended operating environment temperature of the electronic device disposed in the space 50s can be maintained. In the example in FIG. 9C, only the current 12 from the second capacitor C2 is supplied to the heater element 702. However, the current 12 from the second capacitor C2 and the current I1 from the first capacitor C1 may be simultaneously supplied to the heater element 702, or the current 12 from the second capacitor C2 and the current I0 from the capacitor C0 may be simultaneously supplied to the heater element 702, according to the electrostatic capacitances of the capacitor C0, the first capacitor C1, and the second capacitor C2. The current 12 from the second capacitor C2, the current I0 from the capacitor C0, and the current I1 from the first capacitor C1 may be simultaneously supplied to the heater element 702.

Further, when the temperature in the space 50s decreases to the third temperature (for example, 70° C.), the third switch element SW3 is turned on as illustrated in FIG. 9D. When the third switch element SW3 is turned on, stored charges are supplied as a current 13 from the fully charged third capacitor C3 to the heater element 702 through the diode D4. Accordingly, not only the capacitor C0, the first capacitor C1, and the second capacitor C2, but also the third capacitor C3 can continue to supply the power to the heater element 702. Accordingly, the space 50s in the base 1110 can be prevented or delayed from being rapidly brought into a low-temperature state, and the state within a recommended operating environment temperature of the electronic device disposed in the space 50s can be maintained. In the example in FIG. 9D, only the current 13 from the third capacitor C3 is supplied to the heater element 702. However, the current 13 from the third capacitor C3, and the current 12 from the second capacitor C2 may be simultaneously supplied to the heater element 702, the current 13 from the third capacitor C3, and the current I1 from the first capacitor C1 may be simultaneously supplied to the heater element 702, or the current 13 from the third capacitor C3 and the current I0 from the capacitor C0 may be simultaneously supplied to the heater element 702, according to the electrostatic capacitances of the capacitor C0, the first capacitor C1, the second capacitor C2, and the third capacitor C3. The current 13 from the third capacitor C3 and the current I0 from the capacitor C0, the current I1 from the first capacitor C1, and the current 12 from the second capacitor C2 may be simultaneously supplied to the heater element 702. In the examples illustrated in FIGS. 9A to 9D, the first switch element SW1 of the first circuit segment 704s1 is configured to be turned off at the first temperature (for example, 90° C.), the second switch element SW2 of the second circuit segment 704s2 is configured to be turned off at the second temperature (for example, 80° C.), and the third switch element SW3 of the third circuit segment 704s3 is configured to be turned off at the third temperature (for example, 70° C.). However, the present disclosure is not limited thereto. The first switch element SW1, the second switch element SW2, and the third switch element SW3 may be configured to be turned on at different temperatures. Further, four or more circuit segments may be provided and configured to supply currents to the heater element 702 at more precise temperature settings.

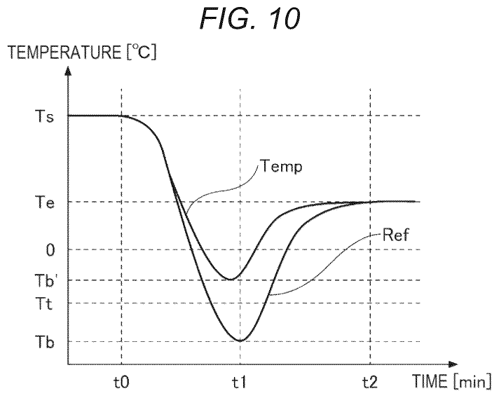

FIG. 10 is a view illustrating an effect of the recovery circuit. FIG. 10 is a view illustrating a temperature change in the space 50s in the base 1110 when the recovery circuit 704 operates after the interlock mechanism of the plasma processing apparatus 1 operates. A horizontal axis represents a time, and a vertical axis represents a temperature. A temperature Ts indicates a temperature in the steady state before the interlock mechanism operates. The temperature Ts is, for example, 100° C. A temperature Te indicates a temperature at which the heat transfer medium in the heat transfer medium flow path 1110a is stable in the steady state after the interlock mechanism operates. The temperature Te is, for example, room temperature. A temperature Tt indicates a lower limit value of the recommended operating environment temperature of the electronic device disposed in the space 50s.

As a Comparative Example, a graph Ref illustrates a temperature change in the space 50s in the base 1110 of the plasma processing apparatus 1 in which the recovery circuit 704 is not provided. In Comparative Example, when the interlock mechanism of the plasma processing apparatus 1 operates, the supply of power from the power source 30 to the element control device 602 is also stopped. Accordingly, the supply of power to the heater element 702 is also stopped. Accordingly, the space 50s in the base 1110 is rapidly brought into a low-temperature state by the heat transfer medium flowing through the heat transfer medium flow path 1110a. In this case, as illustrated by a lowest temperature Tb in the graph Ref in FIG. 10, the temperature in the space 50s falls below the temperature Tt, which is the lower limit value of the recommended operating environment temperature of the electronic device. Accordingly, the state of the recommended operating environment temperature of the electronic device may not be maintained, and the electronic device may not operate normally.

On the other hand, a graph Temp illustrates a temperature change in the space 50s in the base 1110 of the plasma processing apparatus 1 in which the recovery circuit 704 of the present embodiment is provided. In the present embodiment, when the interlock mechanism of the plasma processing apparatus 1 operates, even in the case where the supply of power from the power source 30 to the element control device 602 is stopped, the supply of power to the heater element 702 is continued by the current supplied from at least one of the capacitor C0, the first capacitor C1, the second capacitor C2, and the third capacitor C3. Accordingly, as illustrated by a lowest temperature Tb′ in the graph Temp, the space 50s in the base 1110 can be prevented or delayed from being rapidly brought into a low-temperature state, and the temperature in the space 50s can be prevented from falling below the temperature Tt, which is the lower limit value of the recommended operating environment temperature of the electronic device. Accordingly, the electronic device disposed in the space 50s can be protected, and the electronic device can maintain a normal operation.

### <First Modification>

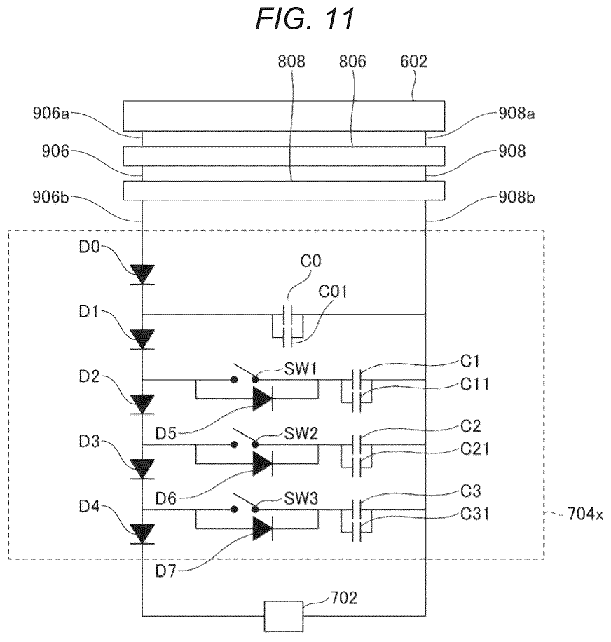

A first modification of the configuration of the recovery circuit 704 will be described with reference to FIG. 11. FIG. 11 is a view illustrating an example of a configuration of a recovery circuit 704x according to the first modification. Like reference numerals will be given to like parts having substantially the same functions as those in the above-described embodiment throughout the first modification, and redundant description thereof will be omitted.

In the first modification, the recovery circuit 704x includes a capacitor C01, a capacitor C11, a capacitor C21, and a capacitor C31 connected in parallel to the capacitor C0, the capacitor C1, the capacitor C2, and the capacitor C3, respectively. The capacitor C01 is an example of the additional power storage element. The capacitor C11 is an example of the first power storage element. The capacitor C21 is an example of the second power storage element. The capacitor C31 is an example of the third power storage element. Electrostatic capacitances of the capacitor C0 and the capacitor C01 may be the same as or different from each other. Similarly, electrostatic capacitances of the capacitor C1 and the capacitor C11 may be the same as or different from each other. Electrostatic capacitances of the capacitor C2 and the capacitor C21 may be the same as or different from each other. Electrostatic capacitances of the capacitor C3 and the capacitor C31 may be the same as or different from each other. Accordingly, a larger amount of charge can be charged, and the space 50s in the base 1110 can be prevented or delayed from being rapidly brought into a low-temperature state for a longer period of time. The current supplied to each of the circuit segments 704s1, 704s2, and 704s3 can be adjusted individually.

### <Second Modification>

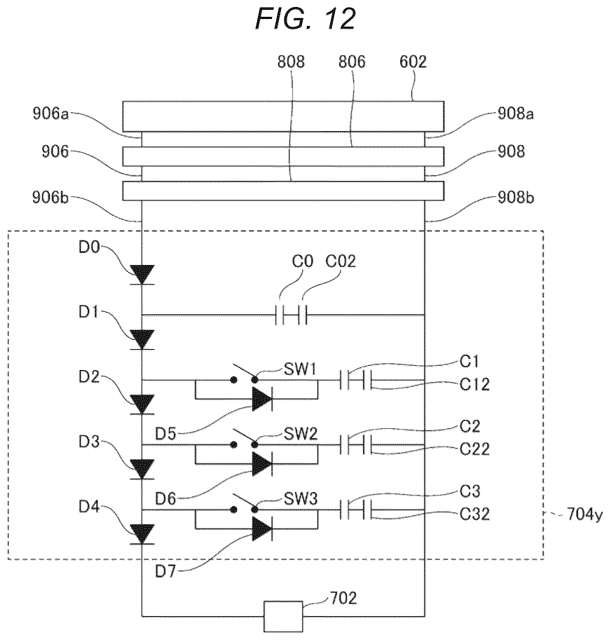

A second modification of the configuration of the recovery circuit 704 will be described with reference to FIG. 12. FIG. 12 is a view illustrating an example of a configuration of a recovery circuit 704y according to the second modification. Like reference numerals will be given to like parts having substantially the same functions as those in the above-described embodiment throughout the second modification, and redundant description thereof will be omitted.

In the second modification, the recovery circuit 704 includes a capacitor C02, a capacitor C12, a capacitor C22, and a capacitor C32 connected in series with the capacitor C0, the capacitor C1, the capacitor C2, and the capacitor C3, respectively. The capacitor C02 is an example of the additional power storage element. The capacitor C12 is an example of the first power storage element. The capacitor C22 is an example of the second power storage element. The capacitor C32 is an example of the third power storage element. Electrostatic capacitances of the capacitor C0 and the capacitor C02 may be the same as or different from each other. Similarly, electrostatic capacitances of the capacitor C1 and the capacitor C12 may be the same as or different from each other. Electrostatic capacitances of the capacitor C2 and the capacitor C22 may be the same as or different from each other. Electrostatic capacitances of the capacitor C3 and the capacitor C32 may be the same as or different from each other. Accordingly, a voltage applied per capacitor can be lowered and a withstand voltage of the capacitor can be secured, and thus a load on the capacitor can be reduced. The current supplied to each of the circuit segments 704s1, 704s2, and 704s3 can be adjusted individually.

### <Third Modification>

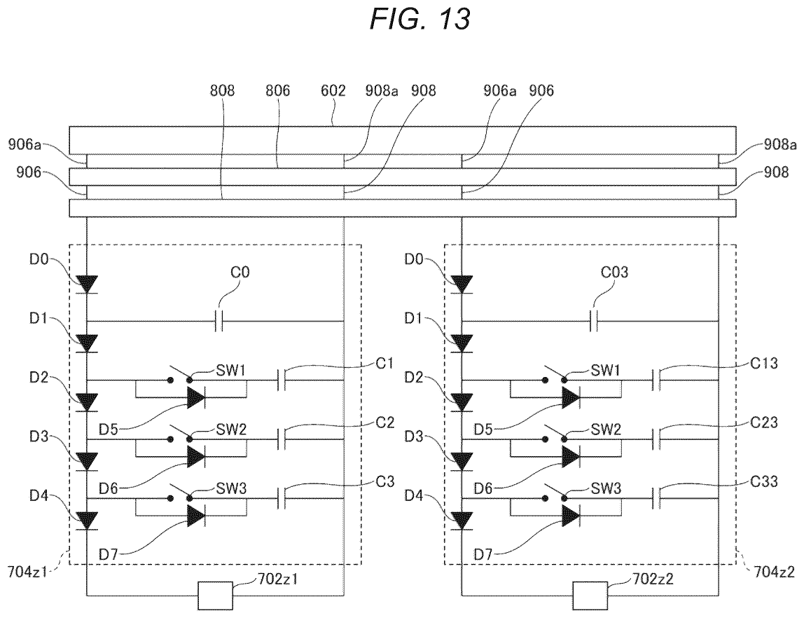

A third modification of the configuration of the recovery circuit 704 will be described with reference to FIG. 13. FIG. 13 is a view illustrating an example of a configuration of recovery circuits 704z1 and 704z2 according to the third modification. Like reference numerals will be given to like parts having substantially the same functions as those in the above-described embodiment throughout the third modification, and redundant description thereof will be omitted.

In the third modification, an electrostatic capacitance of at least one capacitor provided in the recovery circuits 704z1 and 704z2 is different for each region in the space 50s of the base 1110 where heater elements 702z1 and 702z2 are disposed. That is, an electrostatic capacitance of at least one capacitor in the recovery circuit 704z2 is different from an electrostatic capacitance of a corresponding capacitor in the recovery circuit 704z1.

In FIG. 13, a specific region in the space 50s of the base 1110 where the heater element 702z1 is disposed is designated as zone 1, and a region where the heater element 702z2 is disposed, which is different from the zone 1, is designated as zone 2. The recovery circuit 704z1 of the heater element 702z1 included in the zone 1 includes the capacitor C0, the capacitor C1, the capacitor C2, and the capacitor C3. On the other hand, the recovery circuit 704z2 of the heater element 702z2 included in the zone 2 includes a capacitor C03, a capacitor C13, a capacitor C23, and a capacitor C33. The capacitors C0, C1, C2, and C3 in the recovery circuit 704z1 respectively correspond to the capacitors C03, C13, C23, and C33 in the recovery circuit 704z2. In the third modification, at least one of electrostatic capacitances of the capacitor C0 and the capacitor C03, electrostatic capacitances of the capacitors C1 and C13, electrostatic capacitances of the capacitors C2 and C23, and electrostatic capacitances of the capacitors C3 and C33 are different from each other. That is, the electrostatic capacitance of at least one of the capacitors C03, C13, C23, and C33 in the recovery circuit 704z2 is different from the electrostatic capacitance of the corresponding capacitor among the capacitors C0, C1, C2, and C3 in the recovery circuit 704z1. For example, the electrostatic capacitance of the capacitor C03 in the recovery circuit 704z2 may be different from the electrostatic capacitance of the corresponding capacitor C0 in the recovery circuit 704z1. Accordingly, even when a deviation occurs in a temperature distribution in a low-temperature state in the space 50s of the base 1110 in the case where the interlock mechanism operates, an amount of power supplied to the heater element 702 in the space 50s can be finely adjusted for each zone in which the deviation of the temperature distribution occurs.

### <Fourth Modification>

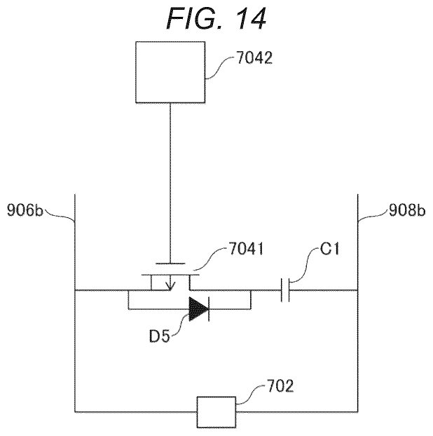

A fourth modification of the configuration of the recovery circuit 704 will be described with reference to FIG. 14. FIG. 14 is a view illustrating an example of the configuration of the recovery circuit 704 according to the fourth modification. Like reference numerals will be given to like parts having substantially the same functions as those in the above-described embodiment throughout the fourth modification, and redundant description thereof will be omitted.

In the fourth modification, a switch element of the recovery circuit 704 includes a metal oxide semiconductor field effect transistor (MOSFET) 7041. A gate terminal of the MOSFET 7041 is connected to a gate control circuit 7042. As the gate control circuit 7042, for example, an electronic circuit such as a central processing unit (CPU) or a micro processing unit (MPU), or an integrated circuit such as an application specific integrated circuit (ASIC) or a field programmable gate array (FPGA) can be employed. The gate control circuit 7042 controls a voltage applied to the gate terminal of the MOSFET 7041 according to a temperature detected by a temperature sensor (not illustrated) disposed in the space 50s, and performs an on/off control of the MOSFET 7041. The gate control circuit 7042 may be disposed in the first control circuit substrate 60 or in the second control circuit substrate 70. In the example in FIG. 14, the MOSFET 7041 is disposed. However, the present disclosure is not limited thereto. Other semiconductor switches may be disposed.

In the fourth modification, the recovery circuit 704 may be disposed outside the space 50s to control the voltage applied to the gate terminal of the MOSFET 7041 according to the temperature detected by a temperature sensor (not illustrated) disposed in the space 50s.

While various exemplary embodiments have been described above, various additions, omissions, substitutions and changes may be made without being limited to the exemplary embodiments described above. Also, the other embodiments may be formed by combining elements in the above-described embodiment and each modification.

Hereinafter, various exemplary embodiments included in the present disclosure will be described in the following (Appendix 1) to (Appendix 19).

### (Appendix 1)

A plasma processing apparatus including:
a plasma processing chamber;
a base disposed in the plasma processing chamber and having a heat transfer medium flow path and a space;
an electrostatic chuck disposed on the base;
at least one first heater element disposed in the electrostatic chuck;
a first control circuit substrate disposed in the space and including at least one control element electrically connected to the at least one first heater element;
a second control circuit substrate disposed in the space and including at least one second heater element electrically connected to the at least one control element; and
a recovery circuit including a plurality of circuit segments electrically connected between the at least one control element and the at least one second heater element and connected in parallel,
a first circuit segment, among the plurality of circuit segments, including at least one first power storage element and a first switch element connected in series, and the first switch element being configured to perform a switching operation based on a temperature in the space.

### (Appendix 2)

The plasma processing apparatus according to Appendix 1, in which
the first circuit segment includes a first parallel rectifying element connected in parallel with the first switch element.

### (Appendix 3)

The plasma processing apparatus according to Appendix 1 or 2, in which
the recovery circuit includes at least one additional power storage element connected in parallel with the first circuit segment.

### (Appendix 4)

The plasma processing apparatus according to any one of Appendixes 1 to 3, in which
the plurality of circuit segments include a second circuit segment connected in parallel with the first circuit segment, and
the second circuit segment includes at least one second power storage element and a second switch element connected in series.

### (Appendix 5)

The plasma processing apparatus of Appendix 3 or 4, in which
the recovery circuit includes
   a first series rectifying element connected between the at least one control element and input of the additional power storage element,
   a second series rectifying element connected between the input of the additional power storage element and input of the first circuit segment, and
   a third series rectifying element connected between the input of the first circuit segment and input of the second circuit segment.

### (Appendix 6)

The plasma processing apparatus according to any one of Appendixes 1 to 5, in which
the at least one first power storage element includes a plurality of first power storage elements connected in parallel.

### (Appendix 7)

The plasma processing apparatus according to any one of Appendixes 1 to 5, in which
the at least one first power storage element includes a plurality of first power storage elements connected in series.

### (Appendix 8)

The plasma processing apparatus according to Appendix 3, in which
the at least one additional power storage element includes a plurality of additional power storage elements connected in parallel.

### (Appendix 9)

The plasma processing apparatus according to any one of Appendixes 3 to 7, in which
the at least one additional power storage element includes a plurality of additional power storage elements connected in series.

### (Appendix 10)

The plasma processing apparatus according to any one of Appendix 3 to 7, in which
the first switch element is a thermostat or a reed switch.

### (Appendix 11)

The plasma processing apparatus according to any one of Appendixes 3 to 10, in which
the at least one first power storage element and the at least one additional power storage element are a capacitor.

### (Appendix 12)

A plasma processing apparatus including:
a plasma processing chamber;
a base disposed in the plasma processing chamber and having a heat transfer medium flow path and a space;
an electrostatic chuck disposed on the base;
a first heater element disposed in the electrostatic chuck;
a second heater element disposed in the space;
a control circuit substrate disposed in the space and including at least one control element electrically connected to at least one of the first heater element and the second heater element; and
a recovery circuit electrically connected between the second heater element and the at least one control element and configured to supply power to the second heater element based on a temperature in the space.

### (Appendix 13)

The plasma processing apparatus according to Appendix 12, in which
the recovery circuit includes a first circuit segment including a first power storage element and a first switch element connected in series, and
the first switch element is configured to perform a switching operation based on the temperature in the space.

### (Appendix 14)

The plasma processing apparatus according to Appendix 12 or 13, in which
the recovery circuit includes a plurality of circuit segments connected in parallel, the plurality of circuit segments include the first circuit segment including the first power storage element and the first switch element connected in series, and
the first switch element is configured to perform the switching operation based on the temperature in the space.

### (Appendix 15)

The plasma processing apparatus according to Appendix 13 or 14, in which
the first circuit segment includes a first parallel rectifying element connected in parallel with the first switch element.

### (Appendix 16)

The plasma processing apparatus according to any one of Appendixes 13 to 15, in which
the plurality of circuit segments include a second circuit segment connected in parallel with the first circuit segment, and
the second circuit segment includes at least one second power storage element and a second switch element connected in series.

### (Appendix 17)

The plasma processing apparatus according to any one of Appendixes 13 to 16, in which
the recovery circuit further includes an additional power storage element connected in parallel with the first circuit segment.

### (Appendix 18)

The plasma processing apparatus according to any one of Appendixes 13 to 17, in which
the first switch element is a thermostat or a reed switch.

### (Appendix 19)

The plasma processing apparatus according to any one of Appendixes 13 to 18, in which
the first power storage element and the additional power storage element are a capacitor.

1. A plasma processing apparatus comprising:
a plasma processing chamber;
a base disposed in the plasma processing chamber, the base including a heat transfer medium flow path and a space;
an electrostatic chuck disposed on the base;
at least one first heater element disposed in the electrostatic chuck;
a first control circuit substrate disposed in the space, the first control circuit substrate including at least one control element electrically connected to the at least one first heater element;
a second control circuit substrate disposed in the space, the second control circuit substrate including at least one second heater element electrically connected to the at least one control element; and
a recovery circuit including a plurality of circuit segments electrically connected between the at least one control element and the at least one second heater element, the plurality of circuit segments being connected in parallel, wherein
a first circuit segment, among the plurality of circuit segments, includes:
at least one first power storage element; and
a first switch element connected in series, and
the first switch element performs a switching operation based on a temperature in the space.

2. The plasma processing apparatus according to claim 1, wherein
the first circuit segment includes a first parallel rectifying element connected in parallel with the first switch element.

3. The plasma processing apparatus according to claim 1, wherein
the recovery circuit includes at least one additional power storage element connected in parallel with the first circuit segment.

4. The plasma processing apparatus according to claim 3, wherein
the plurality of circuit segments further includes a second circuit segment connected in parallel with the first circuit segment, and
the second circuit segment includes:
at least one second power storage element; and
a second switch element connected in series with the at least one second power storage element.

5. The plasma processing apparatus according to claim 4, wherein
the recovery circuit further includes:
a first series rectifying element connected between the at least one control element and an input of the at least one additional power storage element;
a second series rectifying element connected between the input of the at least one additional power storage element and an input of the first circuit segment; and
a third series rectifying element connected between the input of the first circuit segment and an input of the second circuit segment.

6. The plasma processing apparatus according to claim 2, wherein
the at least one first power storage element includes a plurality of first power storage elements connected in parallel.

7. The plasma processing apparatus according to claim 2, wherein
the at least one first power storage element includes a plurality of first power storage elements connected in series.

8. The plasma processing apparatus according to claim 3, wherein
the at least one additional power storage element includes a plurality of additional power storage elements connected in parallel.

9. The plasma processing apparatus according to claim 3, wherein
the at least one additional power storage element includes a plurality of additional power storage elements connected in series.

10. The plasma processing apparatus according to claim 2, wherein
the first switch element is a thermostat or a reed switch.

11. The plasma processing apparatus according to claim 3, wherein
each of the at least one first power storage element and the at least one additional power storage element is a capacitor.

12. A plasma processing apparatus comprising:
a plasma processing chamber;
a base disposed in the plasma processing chamber, the base including a heat transfer medium flow path and a space;
an electrostatic chuck disposed on the base;
a first heater element disposed in the electrostatic chuck;
a second heater element disposed in the space;
a control circuit substrate disposed in the space, the control circuit substrate including at least one control element electrically connected to at least one of the first heater element and the second heater element; and
a recovery circuit electrically connected between the second heater element and the at least one control element, the recovery circuit supplying power to the second heater element based on a temperature in the space.

13. The plasma processing apparatus according to claim 12, wherein
the recovery circuit includes a first circuit segment,
the first circuit segment includes:
a first power storage element; and
a first switch element connected in series with the first power storage element, and
the first switch element performs a switching operation based on the temperature in the space.

14. The plasma processing apparatus according to claim 13, wherein
the recovery circuit further includes a plurality of circuit segments connected in parallel,
the plurality of circuit segments include the first circuit segment, and
the first power storage element and the first switch element are connected in series.

15. The plasma processing apparatus according to claim 14, wherein
the first circuit segment further includes a first parallel rectifying element connected in parallel with the first switch element.

16. The plasma processing apparatus according to claim 15, wherein
the plurality of circuit segments further includes a second circuit segment connected in parallel with the first circuit segment, and
the second circuit segment includes:
at least one second power storage element; and
a second switch element connected in series with the at least one second power storage element.

17. The plasma processing apparatus according to claim 14, wherein
the recovery circuit further includes an additional power storage element connected in parallel with the first circuit segment.

18. The plasma processing apparatus according to claim 17, wherein
each of the first power storage element and the additional power storage element is a capacitor.

19. The plasma processing apparatus according to claim 13, wherein
the first switch element is a thermostat or a reed switch.

20. A plasma processing apparatus comprising:
a plasma processing chamber;
a base disposed in the plasma processing chamber, the base including:
a bottom plate; and
an interior space;
an electrostatic chuck disposed on the base;
a first heater element disposed in the electrostatic chuck;
a printed circuit substrate disposed in the interior space;
a second heater element disposed on the printed circuit substrate;
a control circuit substrate disposed in the interior space, the control circuit substrate including a control element electrically connected to at least one of the first heater element and the second heater element; and
a recovery circuit electrically connected between the second heater element and the control element, the recovery circuit supplying power to the second heater element based on a temperature in the interior space,
the printed circuit substrate and the control circuit substrate being fixed to the bottom plate through spacers.
